(19) United States
(12) Patent Application Publication
(10) Pub. No.: US 2009/0126187 A1
(43) Pub. Date: May 21, 2009

(54) MEMBER SUPPORTING METHOD

(76) Inventors: Masayuki Kajiyama, Osaka (JP); Makito Seno, Osaka (JP); Tadashi Tanno, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/299,034

(22) PCT Filed: Jun. 13, 2007
(86) PCT No.: PCT/JP2007/062367

§ 371 Date: Oct. 30, 2008

(30) Foreign Application Priority Data
Jun. 26, 2006 (JP) 2006-174805

(51) Int. Cl. H05K 13/00

(52) U.S. Cl. 29/760; 29/729

(57) ABSTRACT

A member supporting method for supporting a member using support pins includes: an abutting step (S1) of abutting an end of each of a plurality of support pins facing a surface to be supported of the member against the member by moving the plurality of support pins in a supporting direction which is a direction in which the support pins support the member; and a fixing step (S2) of fixing the plurality of support pins in position with the end of each of the plurality of support pins abutted against the member and located along irregularities on the surface to be supported in the abutting step (S1), and thereby restricting movement of the plurality of support pins in both directions parallel to the supporting direction.

### TECHNICAL FIELD

The present invention relates to a member supporting method for supporting a member of an industrial product when mounting components or performing other operations with respect to the member.

### BACKGROUND ART

Conventionally, a production process of an industrial product such as an electronic device includes various processes such as mounting components on, or applying liquid chemicals to, members such as a printed circuit board (hereinafter referred to simply as a “board”) of the industrial product. Such members often have irregularities in surfaces which are supported when such operations are performed.

Thus, to perform these operations reliably with high accuracy, it is necessary to support the member to be processed in such a way as to conform to the irregularities in the supported surface.

For example, component mounters which mount components on boards are required to mount components reliably with high accuracy on boards of various shapes and sizes.

Besides, the boards on which components are mounted may not only vary from one to another in planar shape and size, but also have components already mounted on the back side. In such cases, it is not possible to support the boards from below by simply using a flat surface.

Thus, techniques have been disclosed concerning methods and apparatus for stably supporting various boards which have different irregularity patterns on the back side because components have been mounted on the supported surfaces of boards, i.e., on the back side (e.g., refer to Patent Document 1).

Conventional techniques for supporting various boards which have different irregularity patterns on the back side will be described below with reference to drawings.

FIG. 1 is a diagram showing an outline of a first conventional board supporting apparatus.

The board supporting apparatus shown in FIG. 1 is equipped with support pins 30 which directly support a board 20 carried in by conveyor rails 15 and actuators 31 which drive the support pins 30 up and down. A stand on which the support pins 30 and actuators 31 are installed is driven up and down by a vertical drive unit 32.

Also, the board supporting apparatus is equipped with a storage device 34 which stores support pin data 34a. The support pin data 34a is information which identifies the support pins 30 to be raised according to the shape of the board 20 and the presence or absence of components 20a on the back side of the board 20.

By giving instructions to the actuators 31 based on the support pin data 34a, an actuator switching controller 33 can raise only those support pins 30 which are located where there is no component 20a directly under and on the board 20 to a predetermined height.

In FIG. 1, the actuators 31 indicated by “1” is in ON state while the actuators 31 indicated by “0” is in OFF state.

That is, as shown in FIG. 1, the first conventional board supporting apparatus turns on only those actuators 31 over which there is no component 20a and thereby raises the support pins 30 on these actuators 31.

This makes it possible to support the board even when components have been mounted on the back side of the board.

Also, techniques have been disclosed concerning an apparatus which supports boards using elasticity of springs (e.g., refer to Patent Document 2).

FIG. 2 is a diagram showing an outline of a second conventional board supporting apparatus.

The board supporting apparatus shown in FIG. 2 is equipped with pistons 40 which support the board 20, springs 41 which give upward urging forces to the pistons 40, and cylinders 42 filled with a viscous fluid which serves as a damper in relation to movements of the pistons 40.

When supporting the board 20, the pistons 40 and the like are raised upward by a vertical drive unit 44 as shown in the right diagram of FIG. 2. Consequently, the right piston 40 which abuts the component 20a sinks down as the spring 41 contracts and supports the board 20 via the component 20a. On the other hand, the left piston 40 located where there is no component 20a supports the board 20 by abutting it directly.

In this way, even when a component has been mounted on the back side of a board, the board supporting apparatus shown in FIG. 2 can support the board from under the component using the elasticity of the spring 41.

Also, techniques have been disclosed concerning an apparatus which support boards using an electro-rheological fluid which can reversibly change viscosity in units of milliseconds by the application of a voltage (e.g., refer to Patent Document 3).

FIG. 3 is a diagram showing an outline of a third conventional board supporting apparatus.

The board supporting apparatus shown in FIG. 3 supports a board 20 from below using an electro-rheological fluid 52 covered with an elastic membrane 51. The electro-rheological fluid 52 covered with the elastic membrane 51 is encased in a container 50. Two electrodes are installed in the elastic membrane 51 and voltage is applied to the electro-rheological fluid 52 by a power supply unit 54.

When a component is mounted on the board 20 from above, the container 50 is raised by a vertical drive unit 55 as shown in the right diagram of FIG. 3. With the elastic membrane 51 deformed according to an irregularity pattern on the back side of the board 20, the power supply unit 54 is switched on and a predetermined voltage is applied to the electro-rheological fluid 52. As the predetermined voltage is applied, the electro-rheological fluid 52 is transformed into a semisolid state.

This makes it possible to support a board according to an irregularity pattern on the back side of the board even when components have been mounted on the back side.

[Patent Document 1] Japanese Patent No. 2769368

[Patent Document 2] Japanese Unexamined Patent Application Publication No. 7-183700

[Patent Document 3] Japanese Unexamined Patent Application Publication No. 2003-069295

### DISCLOSURE OF INVENTION

However, to support boards using the first conventional board supporting apparatus, it is necessary to store information for specifying the support pins 30 to be raised as support pin data 34a for different types of board which vary in size, locations, and the like of the components mounted on the back side.

Thus, there is a problem that the amount of support pin data 34a increases with increases in the number of types of board to be handled, making it difficult to handle the data.

All the raised support pins 30 travel the same distance. Consequently, when the board which originally should be flat is warped due to environmental or other causes, the board is supported only by the support pins 30 which abut it. Also, when a large number of components have been mounted on the back side of the board, the board is supported by a small number of support pins 30.

There is a problem that these situations not only impair stability of the board, but also impose large loads on the support pins 30 which are in contact with the board.

Furthermore, there is a problem that when the support pins 30 are worn, lowering the position which the upper ends of the support pins 30 can reach when raised, there is no way to correct this. This also impairs the stability of the board and causes unequal loads to be placed on different support pins 30.

Also, when supporting a board using the second conventional board supporting apparatus, the pistons 40 continue to press the board under the urging forces of the springs 41. This may deform the board. To deal with this situation, it is conceivable to use springs with a low elastic modulus, i.e., springs with a weak repulsion, which, however, will decrease bearing capacity of the board. In other words, it is not possible to achieve the original purpose of giving the board a bearing capacity to resist forces exerted when components are mounted from above.

Also, as shown in FIG. 2, when a component 20a has been mounted on the back side of the board 20, the spring 41 of the right piston 40 located under the component 20a contracts more greatly than the spring 41 of the left piston 40 which is in direct contact with the board. That is, the right piston 40 presses the board with a larger force than the left piston 40.

Thus, multiple forces acting upward from the back side of the board may vary greatly from one another in magnitude. This may cause the board to be warped, or displaced from its normal position while components are being mounted.

Even when there is no component on the back side of the board, the forces pressing the board will increase with increases in the thickness of the board, and decrease with decreases in the thickness of the board. That is, the board bearing capacity varies with the thickness of the board.

Also, when supporting a board using the third conventional board supporting apparatus, gap length between the electrodes will vary depending on the presence or absence of components on the back side of the board to be supported. This causes the viscosity of the electro-rheological fluid to vary even when a constant voltage is applied. That is, there is a problem that the force which supports the board varies depending on the presence or absence of components on the back side of the board.

Also, when the board contains irregularities due to notches or components on the back side, the elastic membrane 51 which contains the electro-rheological fluid 52 deforms in such a way as to conform to the external shape of the board as shown in FIG. 3. In this state, the electro-rheological fluid 52 is transformed into a semisolid state by the application of a voltage.

That is, uneven forces act from various directions on the components mounted on the back side of the board. This may result, for example, in deformation of the board, misalignment of the components, and the like.

In this way, the conventional board supporting apparatus sometimes cannot support a board in a stable manner when the supported surface of the supported member contains irregularities such as when components have been mounted on the back side of the board. Also, they may exert unnecessary forces on the board, damaging the board as well as the components already mounted on the board.

In view of the conventional problems, an object of the present invention is to provide a member supporting method which makes it possible to reliably mount components or perform other operations with respect to a member such as a board with high accuracy independently of an irregularity pattern on a surface to be supported of the member.

In order to achieve the object, the member supporting method according to the present invention is a member supporting method for supporting a member using a support, including: abutting an of end support by moving the support in a supporting direction which is a direction in which the support supports the member against the member; and fixing the support in position with the end of the support abutted against the member, and thereby restricting movement of the plurality of supports in both directions parallel to the supporting direction.

In this way, the member supporting method according to the present invention fixes the support moved toward the member in position, with the support abutting the member. This restricts the movement of the support in both directions parallel to the supporting direction.

That is, after the support starts to move, the support can be fixed in a position at which they abut the member. Thus, for example, depending on the presence or absence of irregularities on the surface to be supported of the member, the positions of the supports in the supporting direction may vary when the supports abut the member. However, the member supporting method according to the present invention can support the member against forces applied from the side opposite to the supported surface without exerting unnecessary forces on the member regardless of the positions of the supports in the supporting direction when the supports abut the member.

In the abutting, an end of each of a plurality of supports which are provided in positions facing a surface to be supported of the member may be abutted against the member by moving the plurality of supports in a supporting direction which is a direction in which the supports support the member; and in the fixing, the supports may be fixed in position with the end of each of the plurality of supports abutted against the member and located along irregularities on the surface to be supported in the abutting.

Consequently, for example, each support can support the member at a position corresponding to irregularities on the surface to be supported of the member regardless of the size of the supported member. That is, members of various sizes can be supported in a stable manner.

In the abutting, a holder which slidably holds the supports is moved in the supporting direction, thereby moving the supports simultaneously, and the movement of the holder may be stopped when the end of each of the plurality of supports abut the member; each of the plurality of supports held by the holder may slide, with respect to the holder, in a direction opposite to the supporting direction when the holder moves in the supporting direction after the end of the support abut the member; the holder may include a fixing unit which fixes the plurality of supports in position; and in the fixing, the plurality of supports which are abutted against the member in the abutting, may be fixed in position by the fixing unit, the plurality of supports being at rest with respect to the holder.

Consequently, by moving a holder, an abutting unit can move the plurality of supports all together. Also, since the supports abut the member one after another, the holder continues its movement. However, individual supports can slide with respect to the holder in the direction opposite to the supporting direction. That is, the individual supports can move by shifting in relation to the holder. Thus, the supports abutting the member do not exert unnecessary forces on the member even when the holder subsequently moves in the supporting direction after abutting the member.

Also, even when the supported surface of the member contains irregularities, ends of the plurality of supports abut the surface of the member present in the direction of their movement and subsequently have their movement restricted by the fixing units. This makes it possible to support the member in a stable manner.

In addition, obtaining information about a size of the member; and selecting a plurality of supports which face the surface to be supported, of the member out of a plurality of supports, based on the information about the size of the member obtained in the obtaining may be included. In the abutting, the plurality of supports selected in the selecting may be moved in the supporting direction.

This makes it possible to prevent other objects located in close vicinity to the member, such as conveyor rails which convey the member, from coming into contact with the supports, when supporting the member, for example.

Also, the member may be located above the supports and the supporting direction may go from below upward. In the abutting step, the ends may be caused to abut the member by raising the supports upward. In the fixing step, the vertical movement of the supports may be restricted by fixing the supports in position.

Consequently, by using the member supporting method according to the present invention in an apparatus which performs operations from above a member whose underside contains irregularities, it is possible to stably support the member to be processed.

In addition, in the fixing, the support may be fixed in position by means of frictional resistance between a part of the support and an electro-rheological fluid, generated when a predetermined voltage is applied to the electro-rheological fluid which is in contact with the part of the supports.

This makes it possible to electrically fix the supports in position. That is, a mechanism for fixing the supports in position, for example, can be made more compact than when the supports are mechanically fixed in position.

The component-mounting method according to the present invention is implemented as a method for mounting components on boards supported by the member supporting method according to the present invention. Also, the printing method according to the present invention is implemented as a method for printing a conductive paste on boards supported by the member supporting method according to the present invention.

Since the component-mounting method and printing method use the member supporting method according to the present invention, the board can be supported in a stable mariner even when the back side of the board contains irregularities such as when components have been mounted on the back side of the board to be processed. This makes it possible to mount components or print a conductive paste on the board reliably with high accuracy.

The component-mounting method according to the present invention may include a mounting step of mounting components on the opposite side of the board to the supports with the supports fixed in position in the fixing step, in which the board is conveyed by conveyor rails and the obtaining step may obtain width information about conveyor rail width as the information about the size of the member.

That is, a support to be moved can be selected from among multiple supports according to the width information. This makes it possible, for example, to prevent the supports from coming into contact with the conveyor rails. Note that, the technique for selecting the support to be moved according to the width information may be included in the printing method.

In the component-mounting method and printing method according to the present invention, the board may be a flexible board or a rigid-flex board.

That is, the present invention can support a flexible board made of flexible material as well as a rigid-flex board which is a multilayer board made up of a rigid part on which components are mounted and a flex component which is bendable.

When supporting a board all or part of which is flexible, the board and components mounted on the board are prone to be damaged by inadvertent application of forces. However, the member supporting method according to the present invention restricts the movement of supports after the supports abut the board. That is, the supports do not exert urging forces on the board and can resist forces applied to the board when mounting components on the board or performing other operations with respect to the board.

Also, the present invention can be implemented as a member supporting apparatus equipped with components which execute characteristic steps of the member supporting method according to the present invention. Also, it can be implemented as a component mounter or printer equipped with the member supporting apparatus.

Furthermore, the present invention can be implemented as a program which includes characteristic steps of the member supporting method according to the present invention, a storage medium such as a CD-ROM containing the program, or an integrated circuit. The program can be distributed via transmission media such as communications networks.

The present invention makes it possible to support a member in a stable manner without exerting unnecessary forces when mounting components on, or applying a liquid chemical to, the member.

Thus, the present invention provides a member supporting method which makes it possible to reliably mount components or perform other operations with respect to a member such as a board, with high accuracy independently of an irregularity pattern on a supported surface of the member.

### FURTHER INFORMATION ABOUT TECHNICAL BACKGROUND TO THIS APPLICATION

The disclosure of Japanese Patent Application No. 2006-174805 filed on Jun. 26, 2006 including specification, drawings and claims is incorporated herein by reference in its entirety.

### BRIEF DESCRIPTION OF DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing an outline of a first conventional board supporting apparatus;

FIG. 2 is a diagram showing an outline of a second conventional board supporting apparatus;

FIG. 3 is a diagram showing an outline of a third conventional board supporting apparatus;

FIG. 4 is an overview diagram showing a general view of a board supporting apparatus according to a first embodiment;

FIG. 5 is a side view of the board supporting apparatus according to the first embodiment as viewed from a Y-axis direction;

FIG. 6 is a diagram outlining a configuration of a fixing unit according to the first embodiment;

FIG. 7 is a diagram showing a relationship between ON/OFF states of a switch in a fixing power supply unit and frictional resistance between an ER fluid and elevator shaft;

FIG. 8 is a functional block diagram showing a functional configuration of the board supporting apparatus according to the first embodiment;

FIG. 9 is a flowchart showing an outline of operation performed by the board supporting apparatus according to the first embodiment to support a board;

FIG. 10 is a schematic diagram of operation illustrating the flow of operations shown in the flowchart of FIG. 9;

FIG. 11A is a diagram showing how the board supporting apparatus according to the first embodiment is supporting a board without any component mounted on the back side and FIG. 11B is a diagram showing how the board supporting apparatus according to the first embodiment is supporting a board with components mounted on the back side;

FIG. 12 is a diagram showing how the board supporting apparatus according to the first embodiment supports incoming boards one after another;

FIG. 13 is an overview diagram of a shaft holder according to the first embodiment as viewed from a Z-axis direction;

FIG. 14A is a diagram showing conveyor rails on a component mounter before their width is changed and FIG. 14B is a diagram showing the conveyor rails on the component mounter after their width is changed;

FIG. 15 is a diagram showing an example of wiring used to supply power to multiple fixing units on a group by group basis according to the first embodiment;

FIG. 16 is a diagram showing how the board supporting apparatus according to the first embodiment controls operation of the fixing units according to conveyor rail width;

FIG. 17 is a diagram showing a configuration according to the first embodiment when the shaft holder and a base are integrated into a single unit;

FIG. 18 is a diagram showing a configuration according to the first embodiment when the elevator shaft is used as an electrode;

FIG. 19A is a diagram showing width of notches in a board and FIG. 19B is a diagram showing width of the upper end of a support pin;

FIG. 20 is an overview diagram showing a general view of a board supporting apparatus according to a second embodiment;

FIG. 21 is a side view of the board supporting apparatus according to the second embodiment as viewed from a Y-axis direction;

FIG. 22 is a diagram outlining a configuration of a fixing unit according to the second embodiment;

FIG. 23 is a functional block diagram showing a functional configuration of the board supporting apparatus according to the second embodiment;

FIG. 24 is a schematic diagram showing an outline of operation performed by the board supporting apparatus according to the second embodiment to support a board;

FIG. 25A is a diagram showing how the board supporting apparatus according to the second embodiment is supporting a board without any component mounted on the back side and FIG. 25B is a diagram showing how the board supporting apparatus according to the second embodiment is supporting a board with components mounted on the back side;

FIG. 26 is a diagram showing how the board supporting apparatus according to the second embodiment supports incoming boards one after another;

FIG. 27 is a diagram showing a configuration according to the second embodiment when the elevator shaft is used as an electrode;

FIG. 28 is a diagram showing a relationship between three states of a switch in a fixing power supply unit and frictional resistance between an ER fluid and elevator shaft;

FIG. 29 is a diagram showing an example of wiring used to switch among three conducting states of multiple fixing units on a group by group basis;

FIG. 30 is a diagram showing how the board supporting apparatus according to the second embodiment controls operation of the fixing units 2a according to conveyor rail width; and

FIG. 31A is a diagram showing an arrangement of six board supporting units and FIG. 31B is a diagram showing an arrangement of four board supporting units.

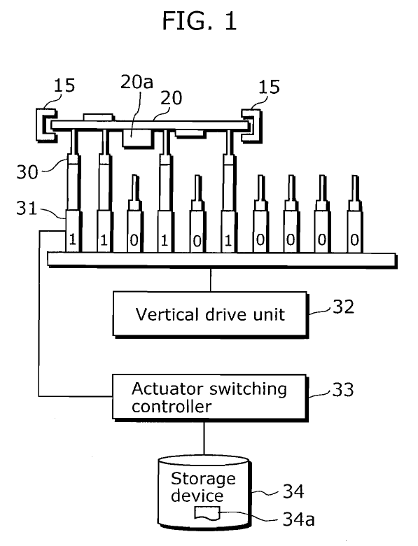

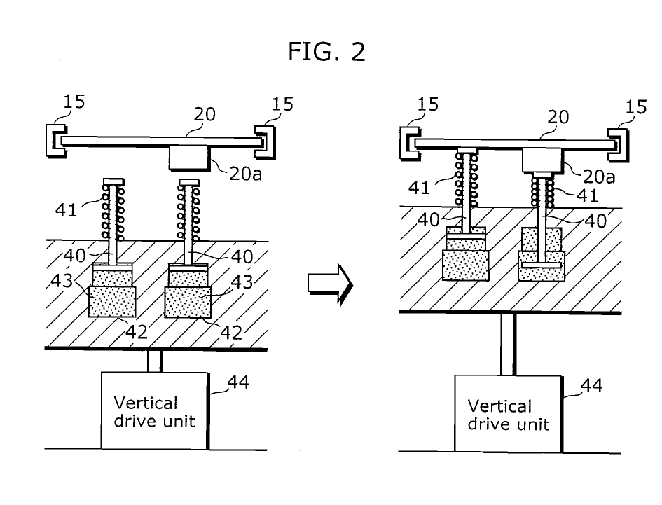

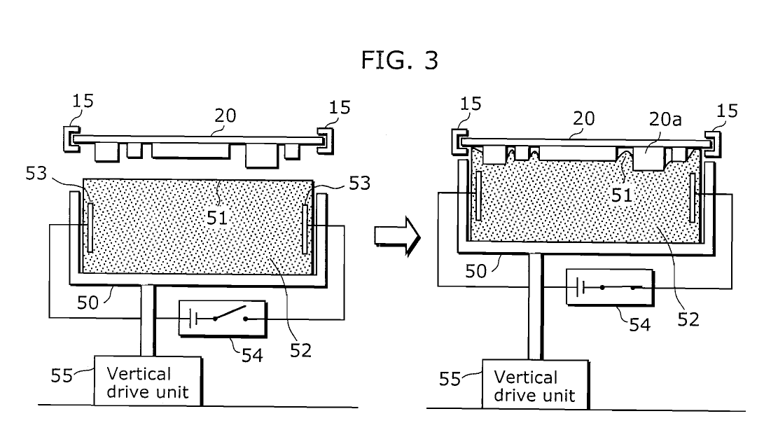

### DESCRIPTION OF SYMBOLS

1, 2 Board supporting apparatus
1a, 2a Fixing unit
1b Actuator
1c Supporting unit
1d, 2b Control unit
3 Support pin
4 Elevator shaft
5 Packing
6 Shaft holder
7, 7a Drive unit
8 Base
10 ER fluid
11 Electrode
12 Fixing power supply unit
15 Conveyor rail
15a Movable rail
15b Fixed rail
101 Board supporting unit
102 Board supporting unit

### BEST MODE FOR CARRYING OUT THE INVENTION

Embodiments of the present invention will be described below with reference to the drawings.

### First Embodiment

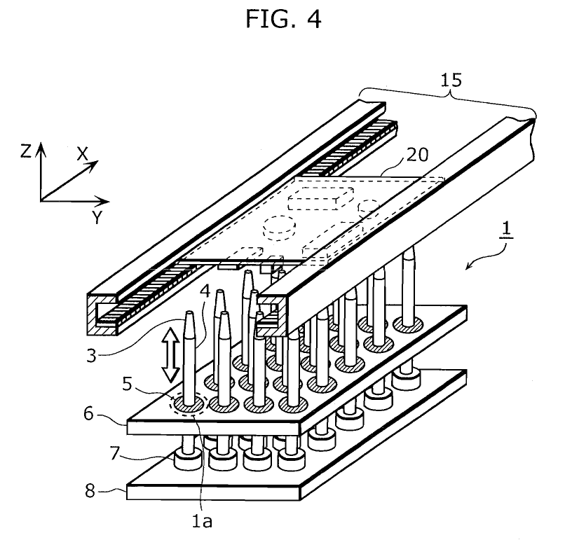

To begin with, a configuration of a board supporting apparatus 1 according to a first embodiment will be described with reference to FIGS. 4 to 8.

FIG. 4 is an overview diagram showing a general view of a board supporting apparatus 1 according to the first embodiment.

The board supporting apparatus 1 shown in FIG. 4 is an example of the member supporting apparatus according to the present invention. It is installed in a component mounter as an apparatus which supports components. The board supporting apparatus 1 can support, from below, a board 20 carried in by conveyor rails 15.

A component mounter equipped with the board supporting apparatus 1 can mount components from above the board 20 as the board 20 is supported by the board supporting apparatus 1 from below. The board 20, which includes any component mounted on its back side, is an example of a member in the member supporting method according to the present invention.

Note that, as shown in FIG. 4, the direction parallel to the conveying direction of the board 20 will be designated as an X-axis direction, the direction parallel to elevator shafts 4, i.e., the direction parallel to the supporting direction of the board will be designated as a Z-axis direction, and the direction perpendicular to the X-axis direction and Z-axis direction will be designated as a Y-axis direction.

The board supporting apparatus 1 is equipped with support pins 3, elevator shafts 4, fixing units 1a, a shaft holder 6, drive units 7, and a base 8. The fixing units 1a have their top face and bottom face covered with packing 5.

The support pin 3 is a component which supports the board 20 either directly or via a component mounted on the back side of the board 20.

The elevator shaft 4 is a component which connects the drive unit 7 and the support pin 3. The support pin 3 and elevator shaft 4 implement the support in the member supporting method according to the present invention.

According to this embodiment, there are twenty pairs of the support pin 3 and elevator shaft 4. Also, there are twenty drive units 7 and twenty fixing units 1a accordingly. All or part of the twenty pairs of the support pin 3 and elevator shaft 4 are installed in such a way as to face the back side of the board 20 when the board 20 is carried in.

The drive unit 7 is a component which abuts the support pin 3 against the board 20 or against a component mounted on the back side of the board 20 by moving the support pin 3 in the supporting direction. The drive unit 7 is fixed to the base 8.

Note that the drive unit 7 is an example of a component which carries out the abutting step in the member supporting method according to the present invention. According to this embodiment, specifically the drive unit 7 is an air cylinder.

The distance by which the support pin 3 is moved upward is equal to or slightly longer than the distance between the upper end of the support pin 3 in its initial position and the back side of the board 20.

That is, upward travel distance of the support pin 3 has been determined such that the upper end of the support pin 3 will abut the back side of the board 20 and that no substantial damage will be caused to the board 20.

The shaft holder 6 is a component which slidably holds the elevator shaft 4. It is fixed parallel to the base 8 or the component mounter at a predetermined distance from the base.

The shaft holder 6 includes the fixing units 1a. When not fixed by the fixing units 1a, the elevator shafts 4 can slide in the shaft holder 6.

The fixing unit 1a is a component which fixes the elevator shaft 4 in position with the support pin 3 abutting the board 20 and thereby restricts the vertical movement of the elevator shaft 4. Details of the fixing unit 1a will be described later with reference to FIG. 6.

The base 8 is a stand which serves as a basis for the board supporting apparatus 1. The base 8 is fixed to the component mounter and occupies a constant relative position within the component mounter.

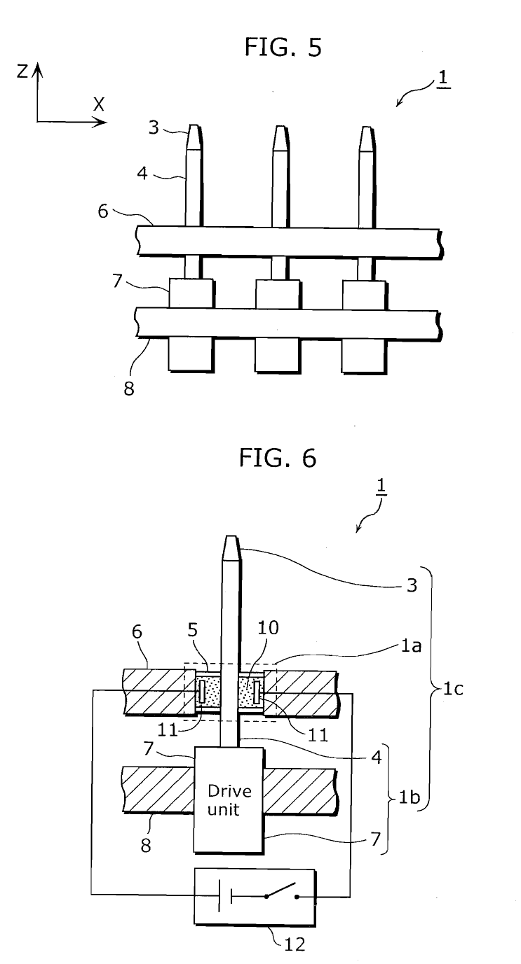

FIG. 5 is a side view of the board supporting apparatus 1 as viewed from a Y-axis direction. It looks alike when viewed from an X-axis direction.

That is, the base 8 and the shaft holder 6 are parallel to each other and the elevator shafts 4 are perpendicular to the base 8 and the shaft holder 6.

FIG. 6 is a diagram outlining a configuration of the fixing unit 1a.

As shown in FIG. 6, the fixing unit 1a has an electro-rheological fluid (hereinafter referred to as an “ER fluid”, where ER stands for Electro-Rheological) 10, the packing 5 which encloses the ER fluid 10 in the fixing unit 1a, and two electrodes 11.

The drive unit 7 and elevator shaft 4 make up an actuator 1b while the actuator 1b, the fixing unit 1a, the elevator shaft 4, and the support pin 3 make up a supporting unit 1c. That is, the board supporting apparatus 1 has twenty supporting units 1c.

The two electrodes 11 of each fixing unit 1a are connected to a fixing power supply unit 12. When the fixing power supply unit 12 is switched on, a voltage is applied to the ER fluid 10.

The ER fluid 10 can reversibly change viscosity in units of milliseconds by the application of a voltage as described above.

That is, by increasing the viscosity by the application of a predetermined voltage to the ER fluid 10, it is possible to increase the frictional resistance between the elevator shaft 4 and the ER fluid 10.

The elevator shaft 4 is substantially fixed to the fixing unit 1a by the increased frictional resistance. That is, the elevator shaft is fixed in this place. Consequently, the vertical movement of the elevator shaft 4 and support pin 3 are restricted. Also, since the viscosity changes reversibly, when the application of the voltage is stopped, the frictional resistance is reduced, allowing the elevator shaft 4 to slide in the shaft holder 6.

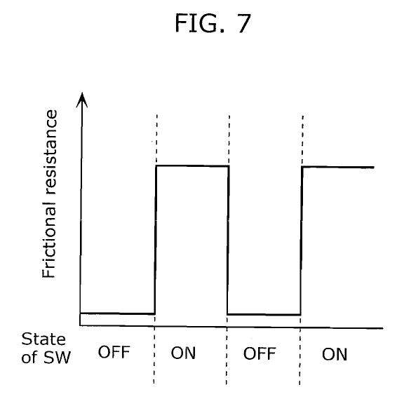

FIG. 7 is a diagram showing a relationship between ON/OFF states of a switch in the fixing power supply unit 12 and frictional resistance between the ER fluid 10 and elevator shaft 4. Note that, in FIG. 7, the switch is denoted by “SW”. This also applies to other diagrams.

As shown in FIG. 7, when the fixing power supply unit 12 is on, value of the frictional resistance is high, and when it is switched off, the value of the frictional resistance is low.

Note that, increase in the value of the frictional resistance between the ER fluid 10 and elevator shaft 4, i.e., increase in the viscosity of the ER fluid 10, varies depending on the magnitude of the voltage to be applied.

Thus, the voltage needed to provide the viscosity which can cause the elevator shaft 4 to be fixed in position against a push-up force exerted by the drive unit 7 on the elevator shaft 4 and support pin 3 and forces acting from above on the board to be supported can be determined as the voltage to be applied to the ER fluid 10 by the fixing power supply unit 12.

ER fluids, which change their viscosity greatly by the application of an electric field, are roughly classified into disperse systems made up of dielectric particulates dispersed in insulating oil and homogeneous systems made up of liquid crystals and a dielectric liquid. Regarding viscosity change behavior in response to the application of an electric field, the former systems exhibit Bingham flow and the latter systems exhibit Newtonian flow. However, both types of fluid are available for use in the fixing device according to the present invention.

The ER fluid normally increases shearing stress by 1000 to 3000 Pa in response to the application of an electric field of 1 to 2 KV/mm. This indicates that a force of 10 to 30 g is generated per 1 square cm of electrode area. According to the present invention, for example, when a rod 5 mm in diameter passes through a 5-mm-ID, 3-cm-long cylindrical electrode unit filled with an ER fluid, an increase in resistance by the application of an electric field of 1 to 2 KV/mm is calculated as (0.4×3.14×3) (cm²)×(10 to 30) (g/cm²)=37 to 110 (g). An actual increase in resistance is close to this value.

After the elevator shaft 4 is fixed in position by the fixing unit 1a, the board is supported by the support pin 3 whose vertical movement is restricted. That is, the push-up force of the drive unit 7 does not need to resist the force exerted from above on the board supported by the support pin 3.

Thus, the drive unit 7 only needs to exert a push-up force enough to push up the elevator shaft 4 and support pin 3 until the upper end of the support pin 3 abuts the back side of the board. Therefore, the push-up force does not damage the board or the components mounted on the back side of the board.

All the fixing units 1a are connected to the fixing power supply unit 12 so as to draw power from it. When the fixing power supply unit 12 is switched on, all the fixing units 1a fix the respective elevator shafts 4 in position. On the other hand, when the fixing power supply unit 12 is switched off, the elevator shafts 4 become able to slide in the shaft holder 6.

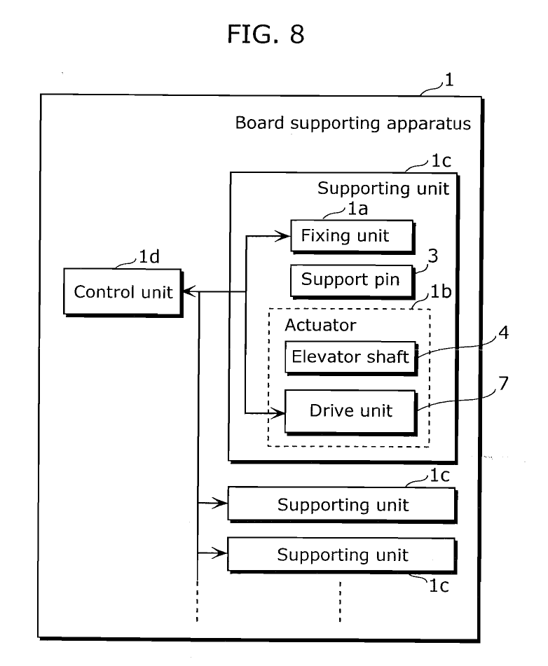

FIG. 8 is a functional block diagram showing a functional configuration of the board supporting apparatus 1.

As shown in FIG. 8, operation of each of the supporting units 1c is controlled by a control unit 1d. The control unit 1d can be implemented by a computer which has a central processing unit (CPU), a storage device, interfaces for information input/output, and the like.

Specifically, the control unit 1d controls the operation of the fixing units 1a by controlling the switching on and off of the fixing power supply unit 12 shown in FIG. 6. Also, the control unit 1d controls the drive unit 7, i.e., it controls the pushing up and lowering of the support pins 3 by the actuators 1b.

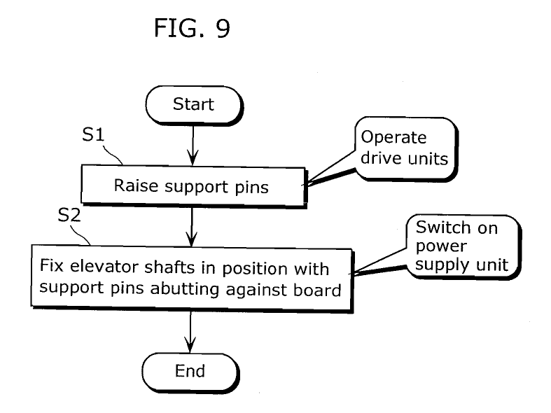

Next, operation of the board supporting apparatus 1 according to the first embodiment will be described with reference to FIGS. 9 to 12.

FIG. 9 is a flowchart showing an outline of operation performed by the board supporting apparatus 1 to support a board.

As shown in the flowchart in FIG. 9, the board supporting apparatus 1 raises all the support pins 3 (S1). Specifically, the control unit 1d brings all the drive units 7 into operation and the drive units 7 raise the respective support pins 3 via the respective elevator shafts 4.

When all the support pins 3 rise and their upper ends abut the board, the elevator shafts 4 are fixed in position (S2). Specifically, when the upper ends of all the support pins 3 abut the board or the components mounted on the back side of the board, the control unit 1d switches on the fixing power supply unit 12. Consequently, a voltage is applied to the ER fluid 10 of all the fixing units 1a and all the elevator shafts 4 are fixed in position.

Note that, according to this embodiment, it is about two seconds after the drive units 7 are brought into operation that the control unit 1d switches on the fixing power supply unit 12. This means that the upper ends of all the support pins 3 abut the board or the components mounted on the back side of the board in this period.

Alternatively, the control unit 1d may switch on the fixing power supply unit 12 upon detecting that all the drive units 7 have finished a push-up operation or that all the elevator shafts 4 have finished rising.

That is, the elevator shafts 4 may be fixed in position when a predetermined time elapses or when a state of a component changes as long as they are fixed with the upper ends of all the support pins 3 abutting against the board or against the components mounted on the back side of the board.

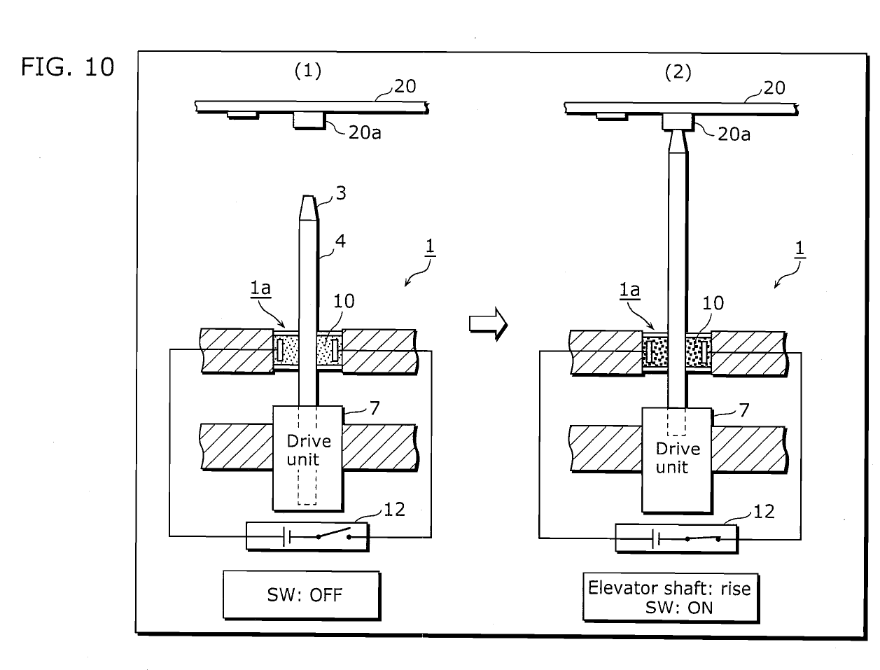

FIG. 10 is a schematic diagram of operation illustrating the flow of operations shown in the flowchart of FIG. 9.

As shown in FIG. 10, (1) before the support pin 3 is raised, the fixing power supply unit 12 is off. (2) When the support pin 3 is raised by the drive unit 7 and abutted against the back side of the board 20 or the component 20a, the fixing power supply unit 12 is switched on. Consequently, the elevator shaft 4 is fixed in position by the fixing unit 1a. That is, the board 20 is supported by the support pin 3.

Originally, the drive unit 7 exerts a push-up force which raises the elevator shaft 4 and support pin 3 to a position where at least the tip of the support pin 3 abuts the board 20. Thus, as shown in FIG. 10, when the component 20a is located right above the support pin 3, the push-up force is exerted continuously on the component 20a if nothing is done.

However, as described above, the drive unit 7 exerts a push-up force only enough to raise the elevator shaft 4 and support pin 3 until the upper end of the support pin 3 directly abuts the board 20.

After the upper end of the support pin 3 abuts the component 20a, the elevator shaft 4 is fixed in position by the fixing unit 1a. That is, even when the drive unit 7 continues to exert a push-up force, the push-up force will not be exerted on the component 20a and board 20 continuously.

Thus, unnecessary forces will never be exerted on the component 20a and board 20, causing damage to them.

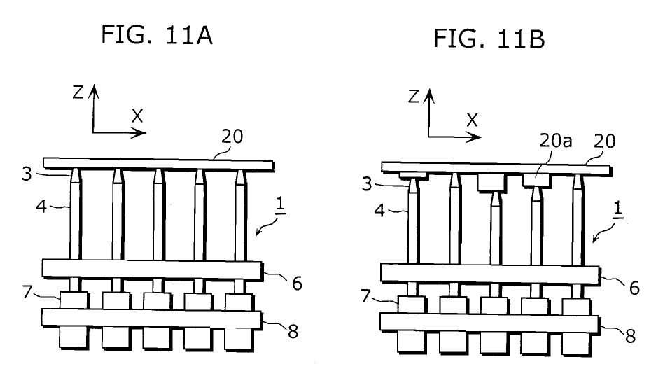

FIG. 11 is a diagram showing how the board supporting apparatus 1 is supporting a board, where FIG. 11A shows a board without any component mounted on the back side while FIG. 11B shows a board with components mounted on the back side.

As shown in FIG. 11A, when the board supporting apparatus 1 is supporting a board 20 without any component mounted on the back side, the upper ends of multiple support pins 3 are located along a flat surface on the back side of the board 20, making it possible to keep the board 20 parallel to the XY plane.

On the other hand, as shown in FIG. 11B, even when the board supporting apparatus 1 is supporting a board 20 with components 20a mounted on the back side, the upper ends of multiple support pins 3 are located along irregularities on the back side of the board 20, making it possible to keep the board 20 parallel to the XY plane.

In this way, whatever irregularity pattern the back side of the board 20 may have, the board supporting apparatus 1 can support the board 20 in a stable manner so that the board 20 will remain parallel to the XY plane, i.e., maintain a normal attitude.

Once components are mounted on the top face of the board 20 supported in this way, the drive units 7 lower all the elevator shafts 4 under the control of the control unit 1d. Subsequently, when the next board is carried onto the board supporting apparatus 1, all the elevator shafts 4 are raised.

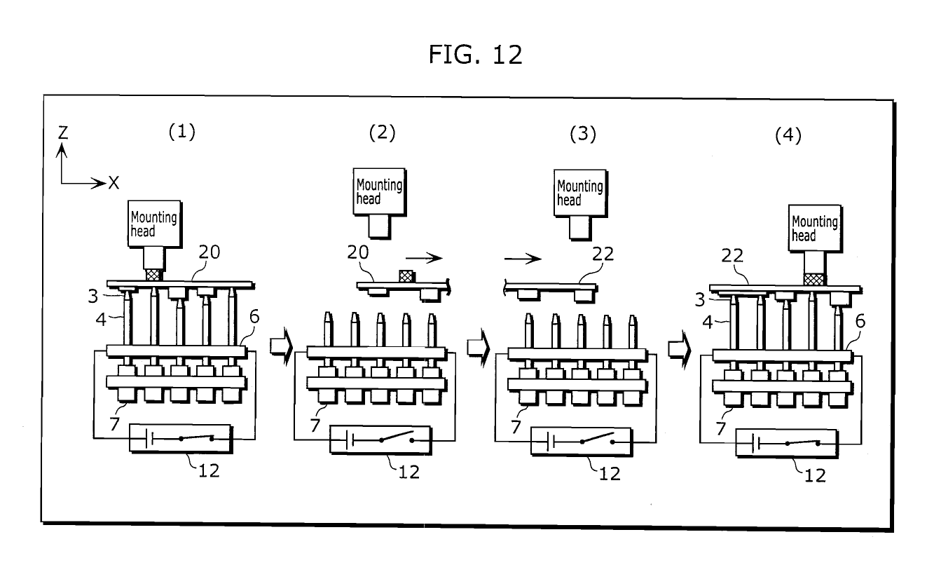

FIG. 12 is a diagram showing how the board supporting apparatus 1 supports incoming boards one after another.

Also, FIG. 12 shows a case in which after a board 20 with components mounted on the back side, a board 22 with components mounted on different positions from those on the board 20 is carried in.

As shown in FIG. 12, (1) when the upper ends of multiple support pins 3 are abutted against the back side of the board 20 and located along irregularities on the back side of the board 20, the fixing power supply unit 12 is switched on. That is, the board 20 is supported in a stable manner. In this state, components are mounted from above the board 20 by a mounting head of the component mounter.

(2) The fixing power supply unit 12 is switched off and all the support pins 3 are returned to an initial position. The board 20 with components mounted is conveyed in the X-axis direction.

(3) The next board 22 is carried onto the board supporting apparatus 1. (4) When the upper ends of multiple support pins 3 are abutted against the back side of the board 22 and located along irregularities on the back side of the board 22, the fixing power supply unit 12 is switched on. That is, the board 22 is supported in a stable manner. In this state, components are mounted from above the board 22 by the mounting head of the component mounter.

In this way, even when supporting boards with different irregularity patterns on the back side one after another, the board supporting apparatus 1 can support the boards precisely according to the respective patterns.

Also, there is no need to prestore information about the irregularity patterns on the back side of individual boards, and the drive units 7 only need to raise the elevator shafts 4 and support pins 3 with a predetermined push-up force.

Also, after the upper ends of all the support pins 3 abut against the board or against the components mounted on the back side of the board, the elevator shafts 4 are fixed in position by the fixing units 1a, and consequently rest positions of the support pins 3 are fixed as well. This allows the support pins 3 to resist the forces exerted from above the board without continuing to apply unnecessary forces to the board.

Even when no component has been mounted on the back side of the board, the back side of the board is not always flat. For example, the board may be warped. In such a case, however, the elevator shafts 4 are fixed in position with the upper ends of multiple support pins 3 being located in conformity with the warped shape of the back side. This makes it possible to support the board in a stable manner.

That is, regardless of whether the back side of a board is flat or irregular, the board supporting apparatus 1 can support the board in such a way that the board will maintain a normal attitude, without damaging the board or components or causing them to deviate from their regular positions.

If a board is smaller than a size that can be supported by the multiple support pins 3, those support pins 3 which are not supporting the board are also raised by the drive units 7. However, the board is supported in such a way as to maintain a normal attitude all the same by those support pins 3 which are abutting the board.

In this way, the board supporting apparatus 1 according to this embodiment can reliably mount components on a board with high accuracy independently of the irregularity pattern on the supported surface of the board.

According to this embodiment, it is assumed that all the fixing units 1a are connected to the fixing power supply unit 12 so as to draw power from it.

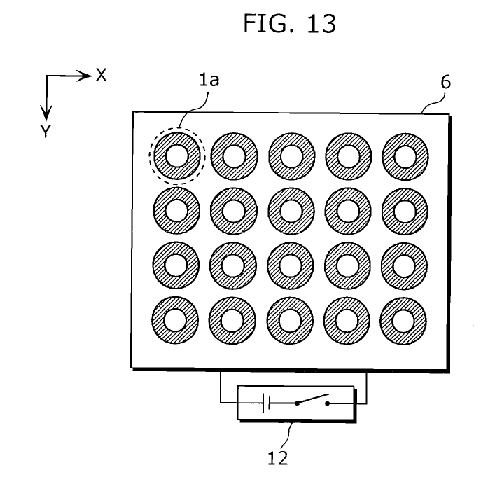

FIG. 13 is an overview diagram of the shaft holder 6 according to this embodiment as viewed from a Z-axis direction.

As shown in FIG. 13, according to this embodiment, multiple fixing units 1a are arranged in the shaft holder 6 and able to draw power from the same fixing power supply unit 12.

That is, when the fixing power supply unit 12 is switched on, all the fixing units 1a fix the respective elevator shafts 4 in position. On the other hand, when the fixing power supply unit 12 is switched off, all the fixing units 1a unfix the respective elevator shafts 4 to make them slidable.

However, operation of the individual fixing units 1a may be controlled separately. Also, information about the size of the board to be supported may be used for this control.

For example, on component mounters, the width of the conveyor rails 15 used to convey the board is changed with changes in the size of the board on which components are mounted. Thus, information about the changed width of the conveyor rails 15 may be used as the information about the size of the board to control the operation of the individual fixing units 1a separately.

Note that, the phrase “the width of the conveyor rails” means the width of the conveyor rails 15 in the Y-axis direction. A similar argument applies to “the width of the board”.

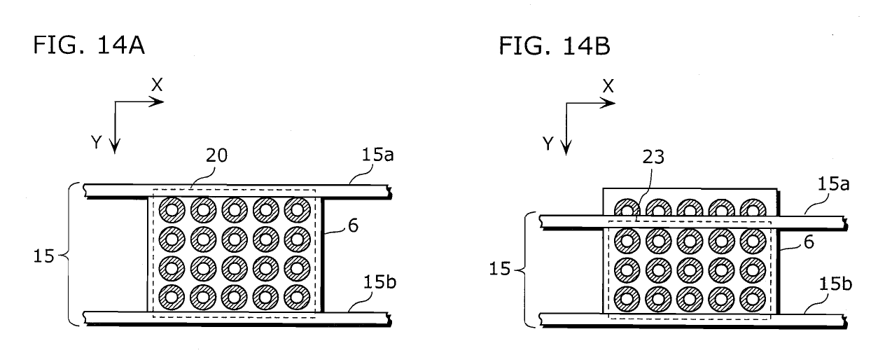

FIG. 14 is a diagram showing a change in the width of conveyor rails on a component mounter, where FIG. 14A shows a state before the change while FIG. 14B shows a state after the change.

The conveyor rails 15 are made up of a movable rail 15a and fixed rail 15b. The width of the conveyor rails 15 can be changed by moving the movable rail 15a in the Y-axis direction.

For example, the board 20 is conveyed by keeping the width shown in FIG. 14A. Then, to convey a board 23 different in size from the board 20, the width of the conveyor rails 15 is changed to the one shown in FIG. 14B to accommodate the size of the board 23.

The width of the conveyor rails 15 is changed through the execution of a program which controls the operation of the component mounter. That is, the component mounter has information about the width of the conveyor rails 15 (hereinafter referred to as the “width information”). The width information includes, for example, “width: 100 mm” and “position of the movable rail: Y=280”.

Thus, by obtaining the width information from the component mounter, the board supporting apparatus 1 can control the operation of each fixing unit 1a based on the width information.

Specifically, each row of fixing units 1a arranged parallel with the X-axis is grouped. Then, a switch is installed to turn on and off power from the fixing power supply unit 12 to each group.

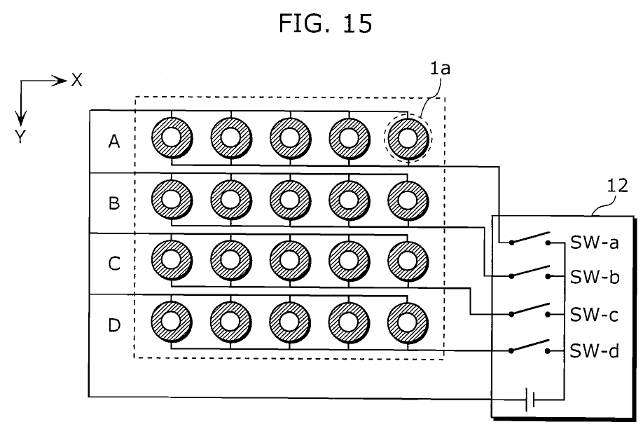

FIG. 15 is a diagram showing an example of wiring used to supply power to multiple fixing units 1a on a group by group basis.

As shown in FIG. 15, the fixing units 1a are organized into groups A to D, each of which is made up of a row of fixing units 1a arranged parallel with the X-axis. Then, wiring is installed to turn on and off power to each of the groups A to D and a switch is installed for each group. The switches for the groups A to D are denoted by SW-a, SW-b, SW-c, and SW-d, respectively.

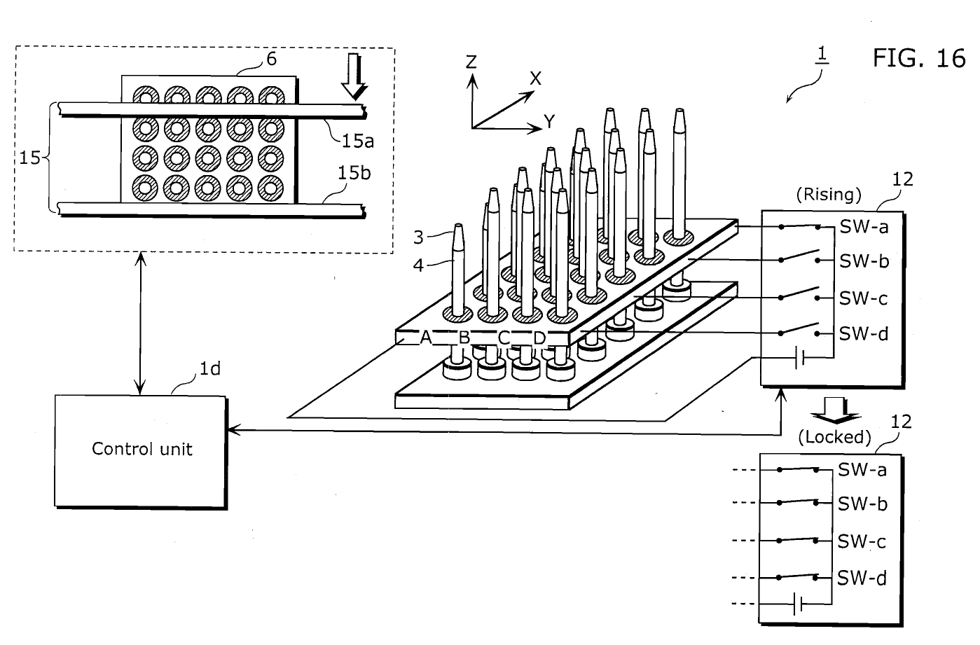

FIG. 16 is a diagram showing how the board supporting apparatus 1 controls operation of the fixing units 1a according to the width of the conveyor rails 15.

For example, it is assumed that a change in the type of target board causes the movable rail 15a to move, causing, in turn, the width of the conveyor rails 15 to be changed to the one shown in the upper left diagram of FIG. 16.

In this case, the control unit 1d obtains width information about the change from the component mounter and selects multiple support pins 3 to be raised.

Specifically, the support pins 3 which correspond to group A do not need to support the board. Thus, SW-a is turned on to fix the elevator shafts 4 corresponding to group A in position by the fixing units 1a. In this state, all the drive units 7 are brought into operation.

Consequently, as shown in FIG. 16, only the support pins 3 corresponding to groups B and C other than group A rise. That is, the board supporting apparatus 1 selects multiple support pins 3 including multiple support pins 3 facing the back side of the board to be supported, based on the obtained width information. Furthermore, the board supporting apparatus 1 can move the selected support pins 3 upward.

The control unit 1d turns on SW-b, SW-c, and SW-d, with the upper ends of all the raised support pins 3 abutting against the board or against the components mounted on the back side of the board. Consequently, the raised support pins 3 are fixed, making it possible to support the board in such a way that the board will maintain a normal attitude.

In this way, the board supporting apparatus 1 can select and raise the support pins 3 needed to support the board using the information about the width of the conveyor rails 15. Note that, in this operation, the control unit 1d implements the operations of the obtaining step and selecting step in the member supporting method according to the present invention.

This makes it possible to keep the support pin 3 directly under the movable rail 15a from rising if, for example, a mechanical component is located below the movable rail 15a and it is desired to keep the support pins 3 out of contact with the mechanical component.

Note that, when the component mounter has information which identifies the size of the board on which components will be mounted, the board supporting apparatus 1 may obtain the information which identifies the size of the board instead of the width of the conveyor rails 15 from the component mounter.

Once the size of the board can be identified, it is possible to determine for which group the support pins 3 should be raised. Thus, it is also possible to control the raising of the support pins on a group by group basis described above using the information which identifies the size of the board by obtaining it from the component mounter in this way.

Also, instead of or in addition to selecting and raising the support pins 3 needed to support the board according to the width of the board in the Y-axis direction, the board supporting apparatus 1 may select and raise the support pins 3 needed to support the board by controlling the operation of the fixing units 1a according to the width of the board in the X-axis direction.

In that case, it is only necessary to install an on/off switch for each group of fixing units 1a organized in the Y-axis direction or on/off switches for the individual fixing units 1a. Then the control unit 1d can control the switches by obtaining information needed for the control, for example, from the component mounter.

Even when components have been mounted on the back side of a board, the board supporting apparatus 1 according to this embodiment can support the board according to the irregularity pattern on the back side of the board regardless of how the components have been arranged.

Thus, when the board supporting apparatus 1 raises only the support pins 3 needed to support the board, taking into consideration, for example, the widths of the board in both the X-axis and Y-axis directions, there is no need for information about locations of the components on the back side of the board unlike the first conventional board supporting apparatus.

Consequently, when storing information used to raise only the support pins 3 needed to support the board, all that is necessary is to store only information about the widths of the board in the X-axis and Y-axis directions. That is, it is necessary to store and manage a small amount of information than the first conventional board supporting apparatus.

Also, since all the support pins 3 directly under the board are raised and used to support the board regardless of the presence or absence of components on the back side of the board, it is possible to support the board more stably than the first conventional board supporting apparatus.

Also, the operation of the drive units 7 may be controlled instead of controlling the operation of the fixing units 1a. For example, in the example shown in FIG. 16, the control unit 1d operates only the drive units 7 for groups B to D. This can also keep the support pins 3 which correspond to group A, i.e., the support pins 3 which do not need to support the board, from rising.

Also, according to this embodiment, the shaft holder 6 is fixed parallel to the base 8 or component mounter at a predetermined distance from the base 8. That is, there is no need for the shaft holder 6 to move with respect to the base 8 and may be integrated into a single unit with the base 8.

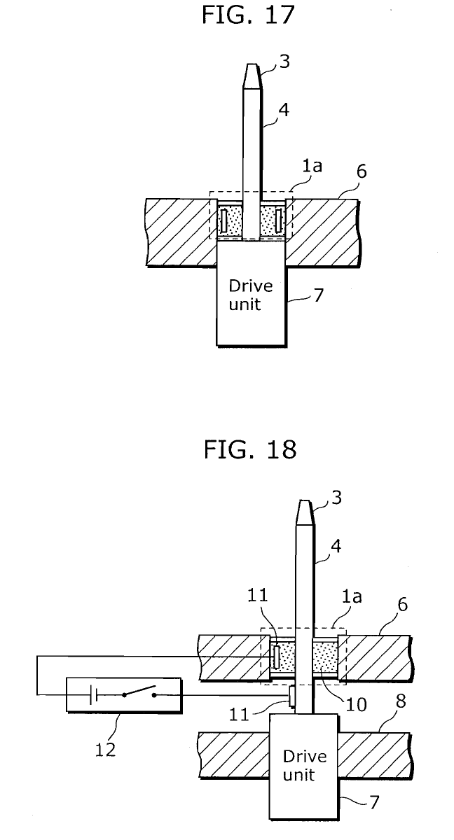

FIG. 17 is a diagram showing a configuration in which the shaft holder 6 and base 8 are integrated into a single unit.

As shown in FIG. 17, the drive unit 7 is implanted in the shaft holder 6. Also, the shaft holder 6 is fixed in place in the component mounter. That is, the shaft holder 6 in FIG. 17 combines the functions of the shaft holder 6 and base 8 in FIG. 6.

This, for example, makes the board supporting apparatus 1 more compact.

The fixing unit 1a, which contains the ER fluid 10, has two electrodes 11 in the ER fluid 10 to apply a voltage to the ER fluid 10.

However, the electrodes 11 may be installed in another location. For example, when at least a flank of the elevator shaft 4 is made of metal, the elevator shaft 4 may be used as an electrode to apply voltage to the ER fluid 10 by placing one of the two electrodes 11 in contact with the elevator shaft 4.

FIG. 18 is a diagram showing a configuration in which the elevator shaft 4 is used as an electrode.

As shown in FIG. 18, the electrode connected to the negative side of the fixing power supply unit 12, for example, is placed in contact with the elevator shaft 4. Even with this configuration, when the fixing power supply unit 12 is switched on, a voltage is applied to the ER fluid 10.

The support pin 3 is not specifically limited in material and may be made of rubber, metal, plastics, or the like. In short, any material of any shape may be used as long as it can support the member to be supported.

When supporting a board which has a notch, the upper end of the support pin 3 may fall into the notch, making it impossible to support the board in such a way that the board will maintain a normal attitude.

To avoid this situation, the upper end of the support pin 3 can be made large enough not to fall into the notch.

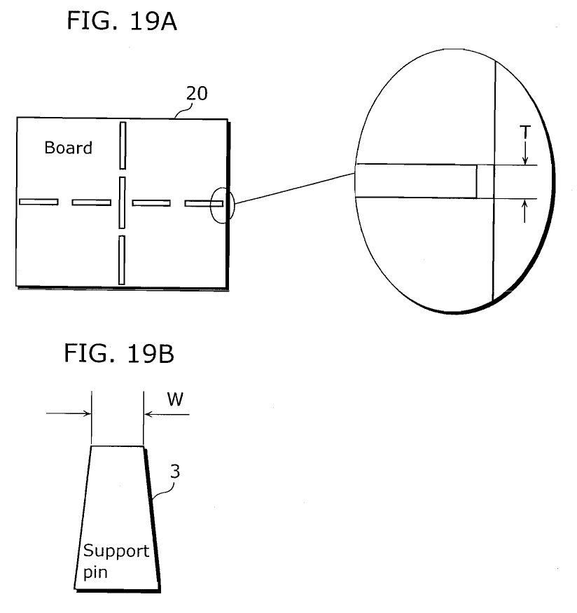

FIG. 19A is a diagram showing width of notches in a board and FIG. 19B is a diagram showing width of the upper end of the support pin 3.

As shown in FIG. 19A, it is assumed that the board supported by the board supporting apparatus 1 has notches whose width is “T”. Also, as shown in FIG. 19B, it is assumed the width of the upper end of the support pin 3 is “W”. Note that, the shape of the support pin 3 is a truncated cone as a whole. That is, the end face of the upper end is circular with a diameter of “W”.

In such a case, if “T<W”, the upper end of the support pin 3 will not enter a notch, and thus the board can be supported in such a way as to maintain a normal attitude.

Also, according to this embodiment, the fixing unit 1a fixes the elevator shaft 4 in position using the ER fluid 10. However, the elevator shaft 4 may be fixed in position by other means.

For example, the elevator shaft 4 may be fixed in position using a magneto-rheological fluid which increases viscosity in response to the application of a magnetic field. Also, the elevator shaft 4 may be fixed in position mechanically. For example, the elevator shaft 4 may be fixed in position by a mechanism which sandwiches the elevator shaft using rubber.

That is, the fixing mechanism or device of the elevator shaft 4 is not limited to any particular one as long as it can practically fix the elevator shaft 4 in position against the push-up force of the drive unit 7 and the force exerted from above on the board to be supported.

Also, the drive unit 7 does not have to be an air cylinder. For example, it may be a mechanism which pushes up the elevator shaft 4 and support pin 3 by means of a motor. That is, the drive unit 7 only needs to raise the elevator shaft 4 and support pin 3 until the upper end of the support pin 3 abuts the board.

Also, the support pin 3 and elevator shaft 4 do not need to be separate units. For example, an upper end portion of the elevator shaft 4 may serve as the support pin 3. Alternatively, the support pin 3 may be pushed up directly by the drive unit 7.

Also, the board supporting apparatus 1 does not need to have twenty pairs of the support pin 3 and elevator shaft 4. It only needs to have one or more pairs of the support pin 3 and elevator shaft 4.

As shown in FIG. 4, when the board supporting apparatus 1 is installed on a component mounter, the board to be supported is supported by the conveyor rails on two sides parallel to the X-axis direction.

Thus, for example, if the board to be supported is small, a pair of the support pin 3 which supports the member and the elevator shaft 4 may be enough to support the board in such a way that the board will maintain a normal attitude. In such a case, only a pair of the support pin 3 and elevator shaft 4 is needed.

Also, the board supported by the board supporting apparatus 1 is not limited to a particular type. For example, it may be a rigid board which uses a nonelastic material as insulating base material or a flexible board which uses an elastic material. Furthermore, it may be a rigid-flex board which is a multilayer board made up of a rigid part on which components are mounted and a flex part which is bendable.

It is assumed here that the board to be supported by the board supporting apparatus 1 is fully or partly flexible such as a flexible board or rigid-flex board.

In this case, even such a weak board and components will practically not be damaged by the support pin 3 if adjustments are made such as setting the maximum height reached by the upper end of the support pin 3 to Lip to a few hundred microns above the back side of the board or decreasing the acceleration of movement of the support pin 3.

Also, after the upper end of the support pin 3 abuts against the board or against a component mounted on the back side of the board, the elevator shaft 4 pushing up the support pin 3 is fixed in position. Consequently, no unnecessary force is applied to the board which is flexible and thus deformable.

In this way, since the board supporting apparatus 1 does not continue to push the board by an elastic force of a spring unlike the second conventional board supporting apparatus, it can support even a deformable board in such a way that the board will maintain a normal attitude.

### Second Embodiment

As a second embodiment of the present invention, description will be given of a board supporting apparatus which raises multiple support pins 3 simultaneously using a single drive unit which raises the shaft holder, in contrast to the first embodiment.

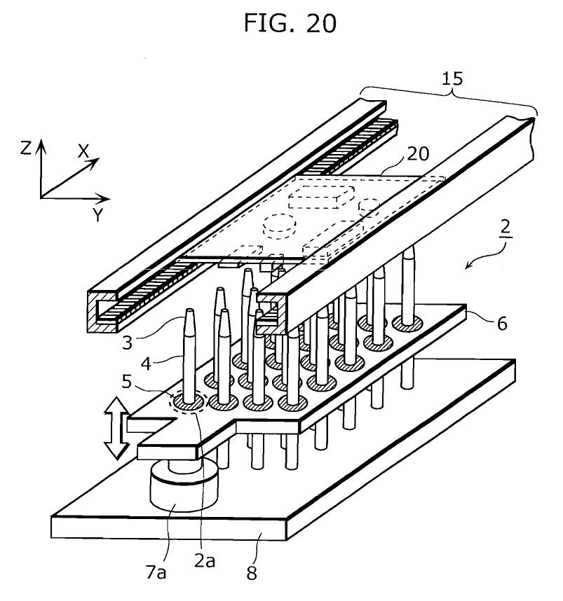

To begin with, a board supporting apparatus 2 according to the second embodiment will be described with reference to FIGS. 20 to 23.

FIG. 20 is an overview diagram showing a general view of the board supporting apparatus 2 according to the second embodiment of the present invention.

The board supporting apparatus 2 shown in FIG. 20 is another example of the member supporting apparatus according to the present invention. It is installed in a component mounter as in the case of the board supporting apparatus 1. Also, it can support, from below, a board 20 carried in by conveyor rails 15.

As shown in FIG. 20, the board supporting apparatus 2 is equipped with support pins 3, elevator shafts 4, fixing units 2a, a shaft holder 6, a drive unit 7a, and a base 8.

The fixing unit 2a is a component which fixes the elevator shaft 4 in position by means of an ER fluid as in the case of the first embodiment. It has its top face and bottom face covered with packing 5.

Also, the board supporting apparatus 2 is equipped with twenty pairs of the support pin 3 and elevator shaft 4 as in the case of the board supporting apparatus 1. However, it has only one drive unit 7a rather than separate drive units for each pair.

The shaft holder 6 contains the fixing units 2a for respective elevator shafts 4. All the fixing units 2a are connected to a fixing power supply unit 12 so as to draw power from it as in the case of the fixing units 1a according to the first embodiment.

The drive unit 7a is fixed to the base 8. Along with movement of the shaft holder 6, the drive unit 7a moves the elevator shafts 4 it holds slidably, causing the upper ends of the multiple support pins 3 to abut the board. The drive unit 7a is another example of a component which carries out the abutting step in the member supporting method according to the present invention. According to this embodiment, specifically, the drive unit 7a is an air cylinder.

A basic flow of operations performed by the board supporting apparatus 2 to support a board is the same as the flow of operations performed by the board supporting apparatus 1 in FIG. 9. That is, the support pins 3 are raised (S1). When the upper ends of the support pins 3 abut against the board or against the components mounted on the back side of the board, the elevator shafts 4 are fixed in position (S2).

However, by raising the shaft holder 6, the board supporting apparatus 2 raises the elevator shafts 4 slidably held by the shaft holder 6. That is, the board supporting apparatus 2 is configured to raise the support pins 3 by raising the shaft holder 6.

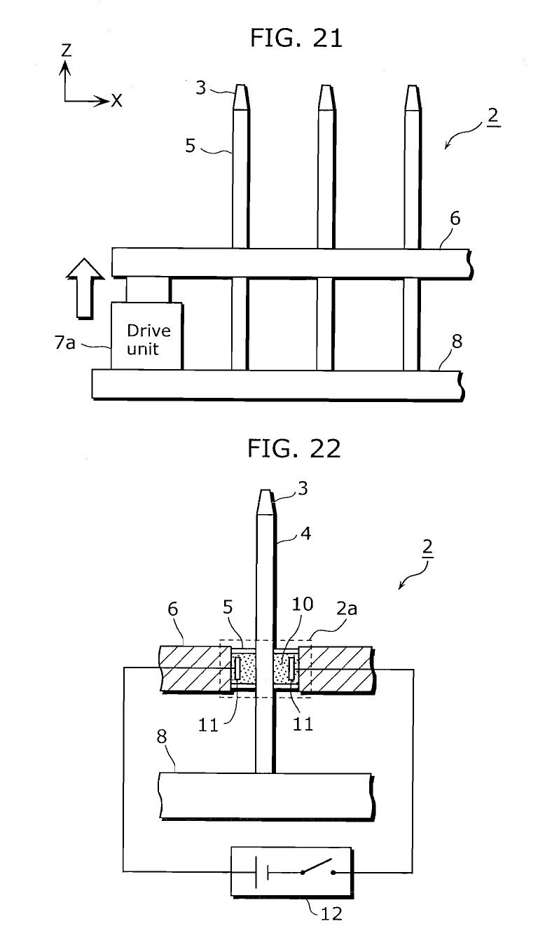

FIG. 21 is a side view of the board supporting apparatus 2 as viewed from a Y-axis direction.

As shown in FIG. 21, the drive unit 7a can raise the shaft holder 6 by pushing it up from below.

The elevator shaft 4 moves along with vertical movement of the shaft holder 6, due to its frictional resistance to the ER fluid 10 to which no voltage is being applied and the packing 5.

Note that, this frictional resistance is such as to prevent the elevator shaft 4 and support pin 3 from falling off the shaft holder 6 under their own weight. That is, the material of the packing 5, type of ER fluid, and the like are determined such that this level of frictional resistance will be developed.

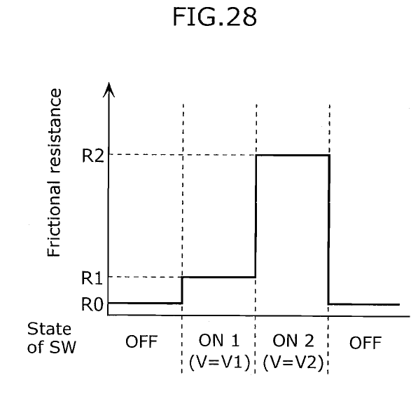

As described later with reference to FIG. 28, frictional resistance of this level may be generated between the elevator shaft 4 and ER fluid by the application of a lower voltage to the ER fluid than when fixing the elevator shaft 4 in position.

FIG. 22 is a diagram outlining a configuration of the fixing unit 2.

As in the case of the fixing unit 1a according to the first embodiment shown in FIG. 6, the fixing unit 2a has an ER fluid 10, packing 5 which encloses the ER fluid 10 in the fixing unit 2a, and two electrodes 11.

Also, as with the fixing unit 1a, the fixing unit 2a can fix the elevator shaft 4 in position as a voltage is applied by the fixing power supply unit 12.

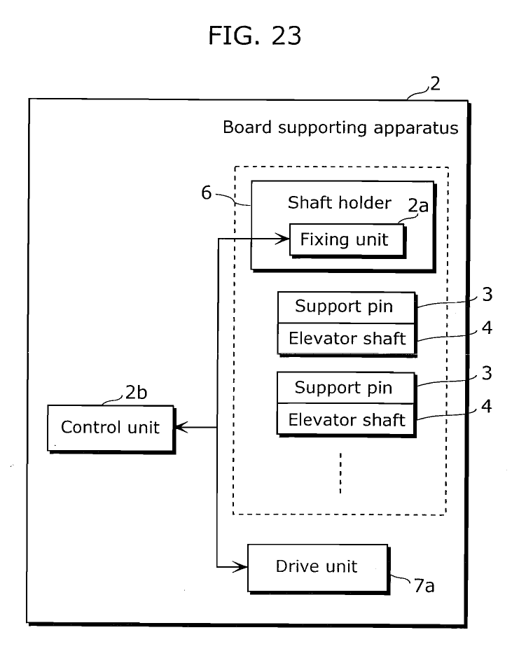

FIG. 23 is a functional block diagram showing a functional configuration of the board supporting apparatus 2.

As shown in FIG. 23, the board supporting apparatus 2 is equipped with a control unit 2b which controls the drive unit 7a and fixing units 2a. Specifically, the control unit 2b controls the drive unit 7a to raise and lower the shaft holder 6.

Also, it controls the multiple fixing units 2a to fix and unfix the elevator shafts 4. Note that, FIG. 23 shows only one fixing unit 2a for simplicity of illustration.

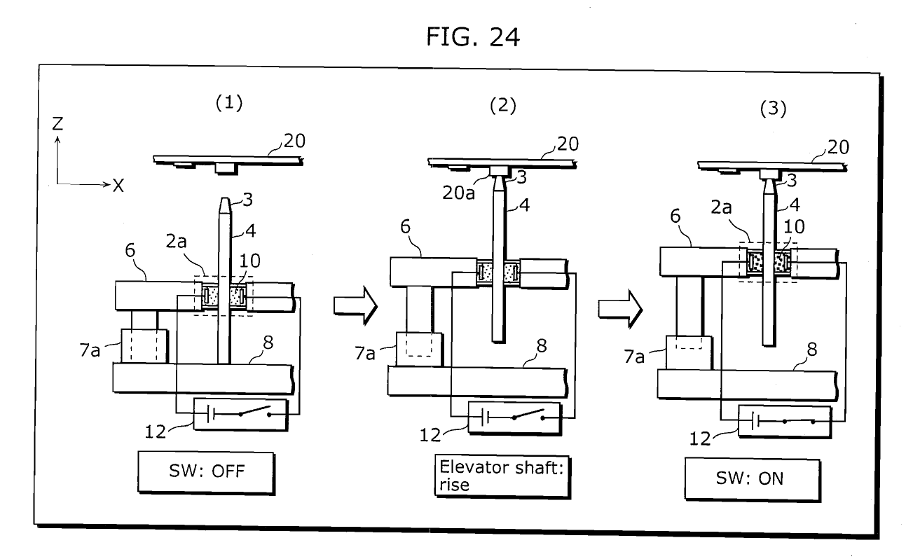

Next, operation of the board supporting apparatus 2 according to the second embodiment will be described with reference to FIGS. 24 to 26.

FIG. 24 is a schematic diagram showing an outline of operation performed by the board supporting apparatus 2.

As shown in FIG. 24, (1) a board 20 is carried onto the board supporting apparatus 2. In this state, the fixing power supply unit 12 is off.

(2) With the fixing power supply unit 12 remaining off, the drive unit 7a raises the shaft holder 6. Consequently, the support pin 3 is raised as well and the upper end of the support pin 3 abuts against the board 20 or against a component 20a mounted on the back side of the board 20.

As shown in FIG. 24, when a component 20a has been mounted on the back side of the board 20, the back side of the board 20 has irregularities. That is, multiple support pins 3 never abut the board 20 or component 20a at the same instant. Thus, even when a support pin 3 abuts a component 20a, the drive unit 7a needs to raise the shaft holder 6 until another support pin 3 abuts the board 20 or another component.

Even in such a case, since the elevator shafts 4 are held slidably by the shaft holder 6, the elevator shaft 4 located under the support pin 3 which abuts the component 20a can slide downward with respect to the shaft holder 6, i.e., in the direction opposite to the supporting direction while being held by the shaft holder 6. That is, the elevator shaft 4 can change relative position with respect to the shaft holder 6 while maintaining relative position on the board supporting apparatus 2.

The frictional resistance between the shaft holder 6 and elevator shaft 4 is such as to prevent the elevator shaft 4 and support pin 3 from falling off the shaft holder 6 under their own weight.

Thus, even when the shaft holder 6 continues to rise with the upper end of a support pin 3 abutting the component 20a, the support pin 3 will not apply an excessive force to the component 20a.

(3) With the upper end of the support pin 3 abutting the board 20 or component 20a, the drive unit 7a stops raising the shaft holder 6 and the fixing power supply unit 12 is switched on under the control of the control unit 2b, causing the elevator shaft to be fixed by the fixing unit 2a.

Note that, as in the case of the first embodiment, it is about two seconds after the drive unit 7a is brought into operation that the control unit 2b switches on the fixing power supply unit 12. This means that the upper ends of multiple support pins 3 located directly under the board 20 abut the board or the components mounted on the back side of the board in this period.

Alternatively, the control unit 2b may switch on the fixing power supply unit 12 upon detecting that the drive unit 79 has finished a push-up operation or that the elevator shafts 4 under the support pins 3 whose upper ends abut the board or components are at rest with respect to the shaft holder 6.

That is, the elevator shafts 4 may be fixed in position when a predetermined time elapses or when a state of a component changes as long as they are fixed when the elevator shafts 4 under the support pins 3 whose upper ends abut the board or components are at rest with respect to the shaft holder 6.

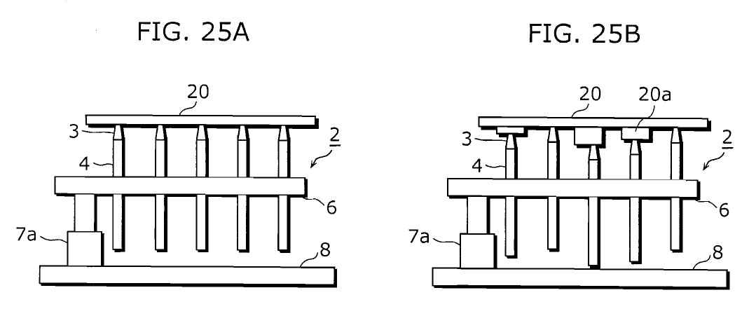

FIG. 25 is a diagram showing how the board supporting apparatus 2 is supporting a board, where FIG. 25A shows a board without any component mounted on the back side while FIG. 25B shows a board with components mounted on the back side.

As shown in FIG. 25A, when the board supporting apparatus 2 is supporting a board 20 without any component mounted on the back side, the upper ends of multiple support pins 3 are located along a flat surface on the back side of the board 20, making it possible to keep the board 20 parallel to the XY plane.

On the other hand, as shown in FIG. 25B, even when the board supporting apparatus 2 is supporting a board 20 with components mounted on the back side, the upper ends of multiple support pins 3 are located along irregularities on the back side of the board 20, making it possible to keep the board 20 parallel to the XY plane.

That is, whatever shape the back side of the board 20 may have, the board supporting apparatus 2 can support the board in such a way that the board 20 will maintain a normal attitude as in the case of the board supporting apparatus 1.

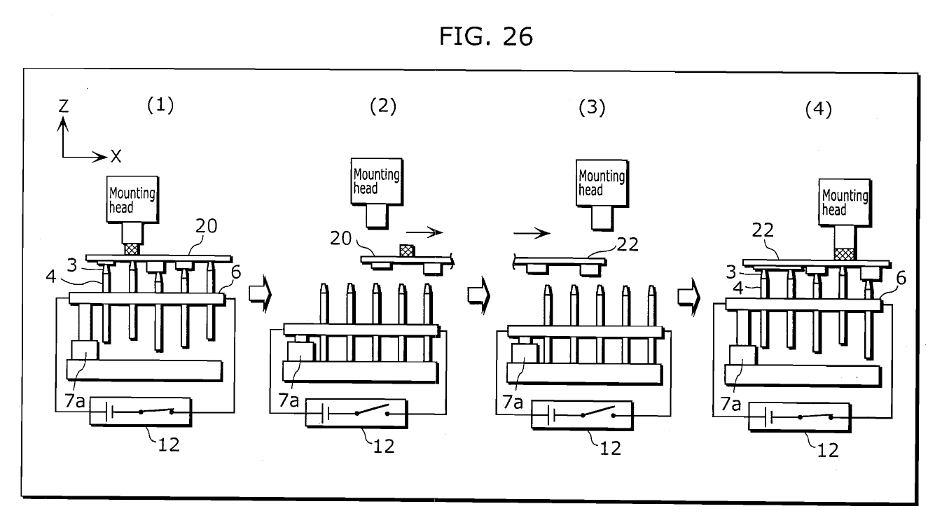

FIG. 26 is a diagram showing how the board supporting apparatus 2 supports incoming boards one after another.

Also, FIG. 26 shows a case in which after a board 20 with components mounted on the back side, a board 22 with components mounted on different positions from the board 20 is carried in.

As shown in FIG. 26, (1) when the upper ends of multiple support pins 3 are abutted against the back side of the board 20 and located along irregularities on the back side of the board 20, the fixing power supply unit 12 is switched on. That is, the board 20 is supported in a stable manner. In this state, components are mounted from above the board 20 by a mounting head of the component mounter.

(2) The fixing power supply unit 12 is switched off and the shaft holder 6 is returned to an initial position. The board 20 with components mounted is conveyed in the X-axis direction.

(3) The next board 22 is carried onto the board supporting apparatus 2. (4) When the upper ends of multiple support pins 3 are abutted against the back side of the board 22 and located along irregularities on the back side of the board 22, the fixing power supply unit 12 is switched on. That is, the board 22 is supported in a stable manner. In this state, components are mounted from above the board 22 by the mounting head of the component mounter.

In this way, even when supporting boards with different irregularity patterns on the back side one after another, the board supporting apparatus 2 can support the boards precisely according to the respective patterns as in the case of the board supporting apparatus 1.

Also, there is no need to prestore information about the irregularity patterns on the back side of individual boards, and the drive unit 7a only needs to raise the shaft holder 6 with a predetermined push-up force.

Also, after the upper ends of all the support pins 3 abut against the board or against the components mounted on the back side of the board, the elevator shafts 4 are fixed in position by the fixing units 2a, and consequently rest positions of the support pins 3 are fixed as well. This allows the support pins 3 to resist the forces exerted from above the board without applying unnecessary forces to the board.

That is, the board supporting apparatus 2 can support the board in such a way that the board will maintain a normal attitude, without damaging the board or components or causing them to deviate from their regular positions.

Also, even when a board is smaller than can be supported by multiple support pins 3, the board is supported in such a way as to maintain a normal attitude all the same by the support pin 3 which is abutting the board, as in the case of the board supporting apparatus 1.

In this way, the board supporting apparatus 2 according to this embodiment can reliably mount components on a board with high accuracy independently of the irregularity pattern on the supported surface of the board.

Note that, with the board supporting apparatus 2, as with the board supporting apparatus 1, the elevator shaft 4 may be used as an electrode to apply voltage to the ER fluid 10.

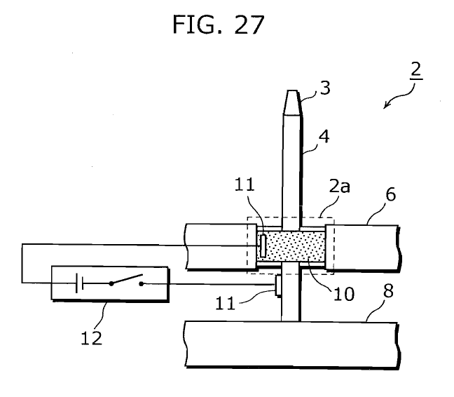

FIG. 27 is a diagram showing a configuration according to the second embodiment when the elevator shaft 4 is used as an electrode. Note that, it is assumed that at least a flank of the elevator shaft 4 is made of metal.

As shown in FIG. 27, the electrode connected to the negative side of the fixing power supply unit 12, for example, is placed in contact with the elevator shaft 4. With this configuration again, when the fixing power supply unit 12 is switched on, a voltage is applied to the ER fluid 10.

Also, with the board supporting apparatus 2, as with the board supporting apparatus 1, the operation of the individual fixing units 2a may be controlled separately using information received from the component mounter.

For example, when the fixing unit 2a is off, the frictional resistance between the shaft holder 6 and elevator shaft 4 is reduced to such a level that the shaft holder 6 and elevator shaft 4 will fall off the shaft holder 6 under their own weight. This can be achieved by selecting an appropriate material of the packing 5 and type of rheological fluid.

Furthermore, instead of selecting whether to apply a voltage to the ER fluid 10, the voltage applied to the ER fluid 10 may be selected from among three levels. For example, the voltage may be allowed to be set to any of three values “0”, “V1”, and “V2” (V1<V2).

Regarding the switching and conducting states of the fixing power supply unit 12, a state in which the voltage applied to the fixing unit 2a by the fixing power supply unit 12 is “0” will be designated as “OFF”, a state in which the voltage is “V1” will be designated as “ON 1”, and a state in which the voltage is “V2” will be designated as “ON 2”.

The viscosity of the ER fluid 10 has a positive correlation with the magnitude of applied voltage. That is, the higher the applied voltage, the higher the viscosity and thus the higher the frictional resistance between the ER fluid 10 and elevator shaft 4.

FIG. 28 is a diagram showing a relationship between three states of a switch in the fixing power supply unit 12 and frictional resistance between the ER fluid 10 and elevator shaft 4.

As shown in FIG. 28, when the state of the switch changes from OFF, to ON 1, and to ON 2, the voltage applied to the ER fluid 10 increases, and so does the viscosity of the ER fluid 10. Consequently, the frictional resistance between the ER fluid 10 and elevator shaft 4 increases as well.

The value “R0” of frictional resistance when the switch is OFF is such that the elevator shaft 4 and the support pin 3 will fall off the shaft holder 6 under their own weight. Thus, when the switch is OFF, the elevator shaft 4 does not rise even when the shaft holder 6 rises.

The value “R1” of frictional resistance when the switch is ON 1 is such that the elevator shaft 4 and the support pin 3 will not fall off the shaft holder 6 under their own weight. Thus, when the switch is set to ON 1, the elevator shaft 4 rises along with the shaft holder 6.

The value “R2” of frictional resistance when the switch is set to ON 2 is such that the elevator shafts 4 can be fixed in position against forces applied from above the board.

If the value of frictional resistance in each state of the switch in the fixing power supply unit 12 is such as described above, the support pins which need to support the board can be raised selectively.

Specifically, the shaft holder 6 is raised by setting the switch to ON 1 for the fixing units 2a corresponding to the support pins 3 which need to support the board and setting the switch to OFF for the fixing units 2a corresponding to the support pins 3 which do not need to support the board.

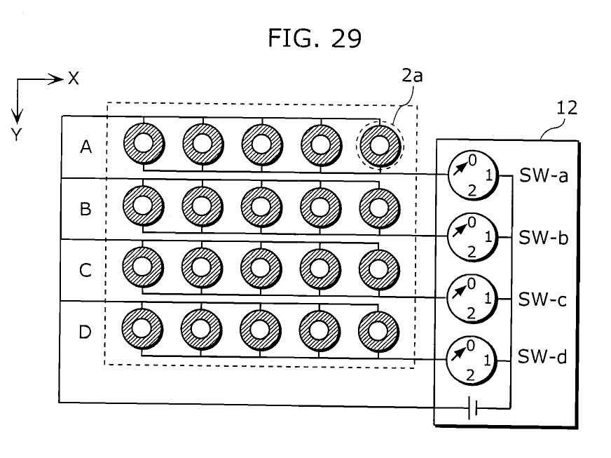

This operation can also be implemented, for example, as shown in a wiring diagram in FIG. 29, by dividing the fixing units 2a into groups and installing a switch for each group to switch among the three conducting states.

FIG. 29 is a diagram showing an example of wiring used to switch among three conducting states of multiple fixing units 2a on a group by group basis.

As shown in FIG. 29, the fixing units 2a are organized into groups A to D, each of which consists of a row of fixing units 2a arranged parallel with the X-axis. Then, wiring is installed to switch each of the groups A to D among OFF, ON 1, and ON 2 and a switch is installed for each group. The switches for the groups A to D are denoted by SW-a, SW-b, SW-c, and SW-d, respectively.

This wiring makes it possible to switch whether to raise the multiple fixing units 2a together with the shaft holder 6 on a group by group basis.

Specifically, when each row of fixing units 2a arranged in the X-axis direction is grouped as shown in FIG. 29, the support pins 3 facing the back side of the board can be raised by selecting them on a group by group basis according to the width of the board in the Y-axis direction.

Also, as described with reference to FIGS. 14 to 16, the component mounter has width information about the conveyor rails 15. By obtaining the width information from the component mounter, the board supporting apparatus 2 can control the operation of the fixing units 2a on a group by group basis according to the width information.

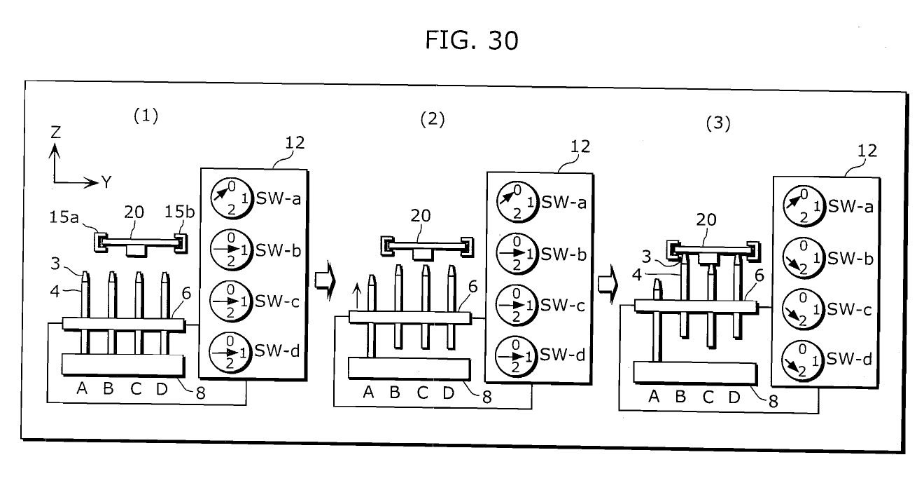

FIG. 30 is a diagram showing how the board supporting apparatus 2 controls operation of the fixing units 2a according to the width of the conveyor rails 15.

As shown in FIG. 30, (1) the rail width decreases as the movable rail 15a moves, and a narrow board 20 is carried in. The control unit 2b of the board supporting apparatus 2 obtains width information from the component mounter and selects groups B to D based on the obtained width information. That is, it turns off SW-a corresponding to group A and sets SW-b, SW-c, and SW-d other than SW-a to ON 1.

(2) The drive unit 7a raises the shaft holder 6. At this time, SW-a is off and the elevator shaft 4 corresponding to group A does not rise. That is, the support pins 3 corresponding to group A do not rise. On the other hand, the support pins 3 corresponding to groups B to D rise.

(3) The upper ends of the raised support pin 3 are located along irregularities on the back side of the board 20. In this state, the control unit 2b sets SW-b, SW-c, and SW-d to ON 2. That is, the fixing units 2a of groups B to D fix the respective elevator shafts 4 in position. Consequently, the board 20 is supported in a stable manner.

In this way, the board supporting apparatus 2 selects multiple support pins 3 including multiple support pins 3 facing the back side of the board to be supported based on the obtained width information. Furthermore, it can move the selected support pins 3 upward. Note that, in this operation, the control unit 2b implements the operations of the obtaining step and selecting step in the member supporting method according to the present invention.

This makes it possible to keep the support pins 3 out of contact with, for example, any mechanical component located below the movable rail 15a, as when the board supporting apparatus 1 according to the first embodiment selects and raises the support pins 3 needed to support the board.

Also, the board supporting apparatus 2 may control the operation of the fixing units 2a using the information which identifies the size of the board instead of the width of the conveyor rails 15 by obtaining it from the component mounter as in the case of the board supporting apparatus 1. Also, instead of or in addition to selecting and raising the support pins 3 needed to support the board according to the width of the board in the Y-axis direction, the board supporting apparatus 2 may select and raise the support pins 3 needed to support the board by controlling the operation of the fixing units 1a according to the width of the board in the X-axis direction.

Regarding the support pin 3, its material and shape are not limited to particular ones, as in the case of the first embodiment. Also, as described with reference to FIG. 19, to support a notched board, the tip of the support pin 3 may be made large enough not to fall into the notches.

Also, the fixing unit 2a may fix the elevator shaft 4 in position using a magneto-rheological fluid instead of the ER fluid 10. Also, the elevator shaft 4 may be fixed in position mechanically.

Also, the drive unit 7a does not have to be an air cylinder. It may be any other mechanism as long as it can raise the elevator shaft 4 and support pin 3 until the upper end of the support pin 3 abuts the board.

Also, the support pin 3 and elevator shaft 4 do not need to be separate units as long as their shape, size, and material are suitable for supporting board.

Also, the board supporting apparatus 2 does not need to have twenty pairs of the support pin 3 and elevator shaft 4. It only needs to have one or more pairs of the support pin 3 and elevator shaft 4. This is because one or more pairs of the support pin 3 and elevator shaft 4 may be able to support a member in such a way that the member will maintain a normal attitude, as described above.

Also, the board supporting apparatus 2 can support any of rigid boards, flexible boards, and rigid-flex boards as in the case of the board supporting apparatus 1.

When the board supporting apparatus 2 is supporting boards which have flexibility, such as flexible boards or rigid-flex boards, adjustments similar to those of the board supporting apparatus 1 can be made.

Specifically, adjustments can be made to the maximum height reached by the upper end of the support pin 3 and acceleration of movement of the support pin 3.

Furthermore, with the board supporting apparatus 2, when the shaft holder 6 rises, the elevator shafts 4 are held slidably by the shaft holder 6. Thus, when the holding force is decreased to a level barely enough to prevent the elevator shafts 4 with the support pins 3 mounted from falling off the shaft holder 6 under their own weight, it becomes easier for the elevator shafts 4 to slide in the shaft holder 6 when the upper ends of the support pins 3 abut against the board or against the components mounted on the back side of the board.

This makes it possible to minimize the force applied to the abutted board and components. Note that, an appropriate value of the holding force can be determined by experiment or the like.

In the first and second embodiments described above, the component mounter is equipped with one board supporting apparatus 1 or 2. However, the component mounter may be equipped with two or more board supporting apparatus 1 or 2.

For example, it is conceivable to incorporate multiple board supporting apparatus 1 or 2 into a component mounter as board supporting units equipped with less than twenty pairs of the support pin 3 and elevator shaft 4. This will allow the component mounter to mount components on boards of various sizes ranging from large to small by changing the number of units.

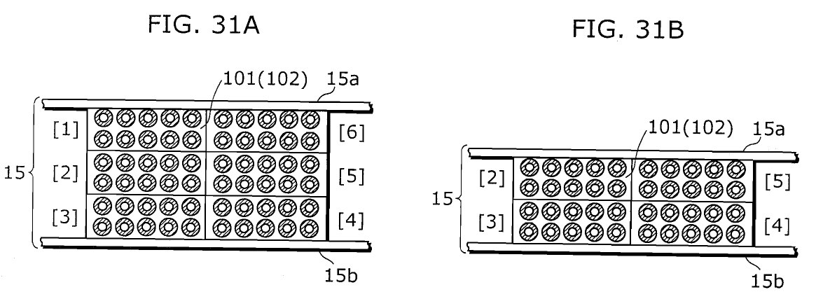

FIG. 31 is a diagram showing exemplary arrangements of unitized board supporting apparatus on a component mounter.

FIG. 31A shows an arrangement of six board supporting units and FIG. 31B shows an arrangement of four board supporting units.

In FIGS. 31A and 31B, a board supporting unit 101 is a unitized version of the board supporting apparatus 1 according to the first embodiment. On the other hand, a board supporting unit 102 is a unitized version of the board supporting apparatus 2 according to the second embodiment. That is, both board supporting apparatus 1 and board supporting apparatus 2 can be unitized.

In FIG. 31A, six board supporting units 101 (102) with unit numbers [1] to [6] are arranged to support a board.

When the component mounter mounts components on a small board, for example, two board supporting units 101 (102) with unit numbers [1] and [6] are removed as shown in FIG. 31B.

Also, the movable rail 15a moves to the position shown in FIG. 31B according to the size of the board to be conveyed. Consequently, the board carried in along the conveyor rails 15 can be supported by four board supporting units 101 (102) with unit numbers [2] to [5].

When the board supporting apparatus 1 or 2 is unitized in this way, board supporting units can be shared, for example, among multiple component mounters compliant with the unitization standards. Also, repairs and other maintenance operations can be carried out on a unit by unit basis, providing time and economic advantages.

Also, in the first and second embodiments of the present invention, description has been given of board supporting apparatus which support boards in a component mounter. However, the present invention is also applicable as a member supporting method and apparatus in other equipment.

For example, the present invention is also applicable to a board supporting method and apparatus in a screen printer which applies a conductive paste such as a solder paste to boards.

When a screen printer applies a conductive paste to a board, a squeegee moves on the board in such a way as to rub the conductive paste on the board which is masked except for the portions to which the conductive paste will be applied. That is, the board is subjected to a force applied from above by the squeegee.

Thus, it is important to support boards firmly on screen printers. Besides, since components may have been mounted on the back side of the boards, i.e., the back side of the boards may be irregular, the present invention is useful as a board supporting method and apparatus for screen printers.

The present invention is also useful, for example, as a supporting method and supporting apparatus for use during grinding, cutting, component-mounting, and other operations to support metal, wood, or the like which contains irregularities in a supported surface.

When some operation is performed on a member, the member supporting method and apparatus according to the present invention abut supports against the member from the side approximately opposite to the side on which the operation is performed and fix the abutting supports in position.

Thus, the present invention is not limited to cases in which the member to be supported is a board with no component mounted on the back side or a board with one or more components mounted on the back side as in the case of the board supporting apparatus 1 and 2, and it can be implemented as a member supporting method and apparatus for various members used in industrial products.

Also, the supporting direction does not need to go from below upward as in the case of the board supporting apparatus 1 and 2. For example, when mounting a member by applying forces to its right flank, the member is supported from left rightward. In that case, a support can be fixed in position by abutting it against the member from left.

In short, as described above, the present invention can be carried out and can support a supported member in such a way that the member will maintain a normal attitude regardless of what material the supported member is made of, what irregularity pattern is contained in the surface opposite the surface subjected to an operation, and in what direction the member is supported.

Specifically, the size, shape, hardness, number and layout of supports as well as fixing forces and the like used to fix the supports in position can be determined depending on the size and weight of the member to be supported, forces applied during operation, and the like.

In this way, the present invention can be implemented as a method and apparatus which support members regardless of the material, supporting direction, and the like of the members, allowing operations on the members to be performed accurately.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to methods and apparatus which support members when operations are performed on the members. In particular, it is useful as a component supporting method and apparatus for a component mounter which mounts components such as semiconductor elements on boards and a screen printer which prints a conductive paste such as a solder paste on boards.

1-11. (canceled)

12. A member supporting method for supporting a member using supports, comprising:
abutting an end of each of supports which are provided in positions facing a surface to be supported of the member against the member by moving the plurality of supports in a supporting direction which is a direction in which the supports support the member; and
fixing the supports in position with the end of each of the plurality of supports abutted against the member and located along irregularities on the surface to be supported in said abutting, and thereby restricting movement of the plurality of supports in both directions parallel to the supporting direction,
wherein, in said fixing, the support is fixed in position by means of frictional resistance between a part of the support and an electro-rheological fluid, generated when a predetermined voltage is applied to the electro-rheological fluid which is in contact with the part of the supports.

13. The member supporting method according to claim 12,
wherein, in said abutting, a holder which slidably holds the supports is moved in the supporting direction, thereby moving the supports simultaneously, and the movement of the holder is stopped when the end of each of the plurality of supports abut the member;
each of the plurality of supports held by the holder slides, with respect to the holder, in a direction opposite to the supporting direction when the holder moves in the supporting direction after the end of the support abut the member;
the holder includes a fixing unit operable to fix the plurality of supports in position with the electro-rheological fluid; and
in said fixing, the plurality of supports which are abutted against the member in said abutting, are fixed in position by the fixing unit, the plurality of supports being at rest with respect to the holder.

14. The member supporting method according to claim 12, further comprising:
obtaining information about a size of the member; and
selecting a plurality of supports which face the surface to be supported, of the member out of a plurality of supports, based on the information about the size of the member obtained in said obtaining,
wherein, in said abutting, the plurality of supports selected in said selecting are moved in the supporting direction.

15. A component-mounting method for mounting a component on a board which is a member supported by the member supporting method according to claim 14, said component-mounting method comprising
mounting a component on the board from a side of the board opposite to the plurality of supports, with the plurality of supports fixed in position in said fixing.

16. A printing method for printing a conductive paste on a board supported by the member supporting method according to claim 14, said printing method comprising:
printing the conductive paste on the board from a side of the board opposite to the plurality of supports, with the plurality of supports fixed in position in said fixing.

17. A component-mounting method for mounting a component on a board which is a member supported by the member supporting method according to claim 13, said component-mounting method comprising
mounting a component on the board from a side of the board opposite to the plurality of supports, with the plurality of supports fixed in position in said fixing.

18. A printing method for printing a conductive paste on a board supported by the member supporting method according to claim 13, said printing method comprising:
printing the conductive paste on the board from a side of the board opposite to the plurality of supports, with the plurality of supports fixed in position in said fixing.

19. A component-mounting method for mounting a component on a board which is a member supported by the member supporting method according to claim 12, said component-mounting method comprising
mounting a component on the board from a side of the board opposite to the plurality of supports, with the plurality of supports fixed in position in said fixing.

20. A printing method for printing a conductive paste on a board supported by the member supporting method according to claim 12, said printing method comprising:
printing the conductive paste on the board from a side of the board opposite to the plurality of supports, with the plurality of supports fixed in position in said fixing.

21. A member supporting apparatus which supports a member using supports, said member supporting apparatus comprising:
an abutting unit operable to abut an end of each of a plurality of supports which are provided in positions facing a surface to be supported of the member against the member by moving the plurality of supports in a supporting direction which is a direction in which the supports support the member; and
a fixing unit operable to fix the plurality of supports in position with the end of each of the plurality of supports abutted against the member and located along irregularities on the surface to be supported by said abutting unit, and thereby restrict movement of the plurality of supports in both directions parallel to the supporting direction,
wherein said fixing unit is operable to fix the supports in position by means of frictional resistance between a part of the supports and an electro-rheological fluid, generated when a predetermined voltage is applied to the electro-rheological fluid which is in contact with the part of the supports.

22. The member supporting apparatus according to claim 21, further comprising
a holder which slidably holds the plurality of supports,
wherein said holder includes said fixing unit;
said abutting unit is operable to move the supports simultaneously by moving the holder in the supporting direction, and to stop the movement of the holder when an end of each of the plurality of supports abut the member;
each of the plurality of supports held by the holder slides, with respect to the holder, in a direction opposite to the supporting direction when the holder moves in the supporting direction after the end of the supports abut the member; and
said fixing unit is operable to fix the plurality of supports which are abutted against the member by said abutting unit in position, the plurality of supports being at rest with respect to the holder.

23. A component-mounter which, having a member supporting apparatus according to claim 22, and which mounts a component on a board which is the member, said component-mounter comprising:
a mounting unit operable to mount a component on the board from a side of the board opposite to the plurality of supports, with the plurality of supports fixed in position by said fixing unit.

24. A printer which, having a member supporting apparatus according to claim 22, and which prints a conductive paste on a board which is the member, said printer comprising:
a printing unit operable to print the conductive paste on the board from a side of the board opposite to the plurality of supports, with the plurality of supports fixed in position by said fixing unit.

25. A component-mounter which, having a member supporting apparatus according to claim 21, and which mounts a component on a board which is the member, said component-mounter comprising:
a mounting unit operable to mount a component on the board from a side of the board opposite to the plurality of supports, with the plurality of supports fixed in position by said fixing unit.

26. A printer which, having a member supporting apparatus according to claim 21, and which prints a conductive paste on a board which is the member, said printer comprising:
a printing unit operable to print the conductive paste on the board from a side of the board opposite to the plurality of supports, with the plurality of supports fixed in position by said fixing unit.
